(19) United States
(12) Patent Application Publication
(10) Pub. No.: US 2025/0183107 A1
(43) Pub. Date: Jun. 5, 2025

(54) SEMICONDUCTOR PACKAGE

(71) Applicant: Samsung Electronics Co., Ltd., Suwon-si (KR)

(72) Inventor: Kwangyong Lee, Suwon-si (KR)

(21) Appl. No.: 18/954,917

(22) Filed: Nov. 21, 2024

(30) Foreign Application Priority Data
Dec. 1, 2023 (KR) 10-2023-0172737

(51) Int. Cl. H01L 23/31; H01L 23/00; H01L 23/538; H01L 25/065

(52) U.S. Cl. CPC H01L 23/3142; H01L 23/3128; H01L 23/5386; H01L 24/32; H01L 25/0657; H01L 2224/32227; H01L 2924/3512

(57) ABSTRACT

A semiconductor package including a package substrate including a first conductive pad, a semiconductor chip disposed on the package substrate and including a second conductive pad, a first adhesive layer formed between the package substrate and the semiconductor chip, a second adhesive layer formed along a side wall of the semiconductor chip, and a conductive line electrically connecting the second conductive pad to the first conductive pad of the package substrate. The first adhesive layer and the second adhesive layer are formed from the same adhesive material and are formed continuously without a boundary therebetween and an outer surface of the second adhesive layer has a slope extending downwardly and outwardly toward the upper surface of the package substrate from the side wall of the semiconductor chip.

### CROSS-REFERENCE TO RELATED APPLICATION

This application is based on and claims priority under 35 U.S.C. § 119 to Korean Patent Application No. 10-2023-0172737, filed on Dec. 1, 2023, in the Korean Intellectual Property Office, the disclosure of which is incorporated by reference herein in its entirety.

### BACKGROUND

Aspects of the inventive concept relate to a semiconductor package, and more particularly, to a semiconductor package having side wirings.

A semiconductor package having side wirings on sides of semiconductor chips is being developed. In the semiconductor package having side wirings, cracks may occur in the side wirings due to structural stress applied to the side wirings, which may disrupt the transmission of signals that operate the semiconductor package, thereby reducing the reliability of the semiconductor package. Therefore, it is required that the side wirings are formed to be stable and maintained stably for a long time in the semiconductor package.

### SUMMARY

Aspects of the inventive concept provide a reliable semiconductor package where side wirings thereof are maintained stably for a long time without the occurrence of crack.

Aspects of the inventive concept provide a reliable semiconductor package that are maintained stably for a long time without cracking of the side wirings by a simplified manufacturing process.

According to an aspect of the inventive concept, there is provided a semiconductor package including a package substrate including one or more first conductive pads on an upper surface thereof, a semiconductor chip disposed on the package substrate and including one or more second conductive pads on an upper surface thereof, a first adhesive layer, having electrical insulation characteristics, formed between the package substrate and the semiconductor chip, a second adhesive layer, having electrical insulation characteristics, formed along a first side wall of the semiconductor chip, and a conductive line electrically connecting the second conductive pad of the semiconductor chip to the first conductive pad of the package substrate. Herein, the first adhesive layer and the second adhesive layer include from the same adhesive material and formed continuously without a boundary therebetween by pressing the same adhesive material between the package substrate and the semiconductor chip, and an outer surface of the second adhesive layer has a first slope extending downwardly and outwardly toward the upper surface of the package substrate from the first side wall.

According to another aspect of the inventive concept, there is provided a semiconductor package including a package substrate including one or more first conductive pads on an upper surface thereof, a plurality of semiconductor chips stacked on the package substrate, each semiconductor chip including one or more second conductive pads on each upper surface thereof, and respective first side walls of the plurality of semiconductor chips are stacked on each other to have a step shape, a plurality of first adhesive layers, having electrical insulation characteristics, formed between the plurality of semiconductor chips and between the package substrate and the semiconductor chip arranged at a lowermost position among the plurality of semiconductor chips, the plurality of first adhesive layers insulating the plurality of semiconductor chips from each other, a plurality of second adhesive layers, having electrical insulation characteristics, formed to correspond to each of the plurality of first adhesive layers along each first side wall of the plurality of semiconductor chips, and a conductive line electrically connecting the second conductive pads of the semiconductor chips to the first conductive pad of the package substrate. Herein, the first adhesive layers and the second adhesive layers formed to correspond to each other may be formed from the same adhesive material, and formed continuously without a boundary therebetween by pressing the same adhesive material between the plurality of semiconductor chips and between the package substrate and the semiconductor chip arranged at the lowermost position among the plurality of semiconductor chips, and outer surfaces of the second adhesive layers may have a slope extending downwardly and outwardly toward the upper surface of the package substrate from the first side walls of the semiconductor chips.

According to another aspect of the inventive concept, there is provided a semiconductor package including a package substrate including one or more first conductive pads on an upper surface thereof, a plurality of semiconductor chips stacked on the package substrate and comprising first side walls stacked on each other to have a step shape, each semiconductor chip including one or more second conductive pads on each upper surface thereof, a plurality of first adhesive layers, having electrical insulation characteristics, formed between the plurality of semiconductor chips and between the package substrate and the semiconductor chip arranged at a lowermost position among the plurality of semiconductor chips, and the plurality of first adhesive layers insulating the plurality of semiconductor chips from each other, a plurality of second adhesive layers, having electrical insulation characteristics, formed to correspond to each of the plurality of first adhesive layers along each first side wall of the plurality of semiconductor chips, a conductive line electrically connecting the second conductive pads of the semiconductor chips to the first conductive pad of the package substrate, a sealing member scaling the plurality of semiconductor chips and the conductive line, and plurality of external terminals formed on the package substrate. Herein, the first adhesive layers and the second adhesive layers formed to correspond to each other may be formed from the same adhesive material, and formed continuously without a boundary therebetween by pressing the same adhesive material between the plurality of semiconductor chips and between the package substrate and the semiconductor chip arranged at a lowermost position among the plurality of semiconductor chips, and each of the second adhesive layers may have a slope extending downwardly and outwardly toward the upper surface of the package substrate from the first side walls of the semiconductor chips.

### BRIEF DESCRIPTION OF THE DRAWINGS

Embodiments will be more clearly understood from the following detailed description taken in conjunction with the accompanying drawings in which:

FIG. 1 is a simplified plan view of a semiconductor package according to some embodiments;

FIG. 2 is a cross-sectional view of a semiconductor package taken along line A-A of FIG. 1 according to some embodiments;

FIGS. 3A to 3C are cross-sectional views sequentially showing a manufacturing process of the semiconductor package of FIG. 2 according to some embodiments;

FIG. 4 is a flow chart sequentially describing a manufacturing process of the semiconductor package of FIG. 2 according to some embodiments;

FIG. 5 is a simplified plan view of a semiconductor package according to some embodiments;

FIG. 6 is a cross-sectional view of a semiconductor package taken along line B-B of FIG. 5 according to some embodiments;

FIGS. 7A to 7E are cross-sectional views sequentially showing a manufacturing process of the semiconductor package of FIG. 6 according to some embodiments;

FIG. 8 is a flow chart sequentially describing a manufacturing process of the semiconductor package of FIG. 6 according to some embodiments;

FIGS. 9A to 9D are cross-sectional views sequentially showing a manufacturing process of the semiconductor package of FIG. 6 according to some embodiments;

FIG. 10 is a flow chart sequentially describing a manufacturing process of the semiconductor package of FIG. 6 according to some embodiments;

FIG. 11 is a cross-sectional view of a semiconductor package according to some embodiments;

FIG. 12 is a cross-sectional view of a semiconductor package according to some embodiments;

FIG. 13 is a cross-sectional view of a semiconductor package according to some embodiments;

FIG. 14 is a cross-sectional view showing a portion of a conventional semiconductor package; and

FIG. 15 is an image showing the occurrence of crack in a side wiring in a conventional semiconductor package.

### DETAILED DESCRIPTION OF THE EMBODIMENTS

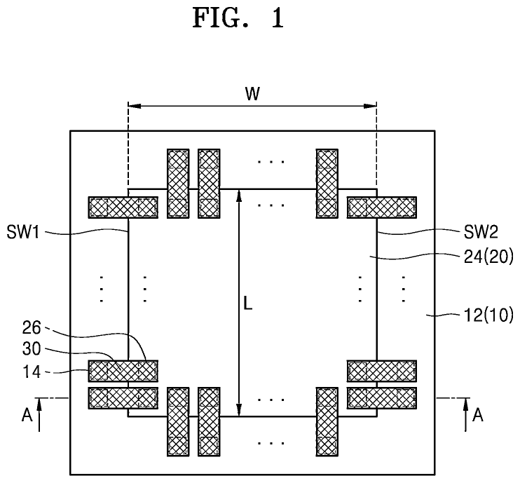

FIG. 1 is a simplified plan view of a semiconductor package according to some embodiments.

Referring to FIG. 1, a semiconductor package according to some embodiments may include a quadrangle-shaped semiconductor chip 20 arranged in a central region of a quadrangle-shaped package substrate 10. FIG. 1 shows that a first electrical insulating layer 12 may be formed on an upper surface of the package substrate 10, and a second electrical insulating layer 24 may be formed on an upper surface of the semiconductor chip 20. The semiconductor chip 20 may be configured in a quadrangle (e.g., a square, a rectangular, a parallelogram, etc.) shape, but is not limited thereto. In addition, the semiconductor chip 20 may have a first length L in a length direction (e.g., a first horizontal direction or X-direction) and have a first width W in a width direction (e.g., a second horizontal direction or Y-direction).

A plurality of first pads 14 may be on the upper surface of the package substrate 10, in which the first pads 14 are arranged adjacent to side walls of the semiconductor chip 20 and surround the semiconductor chip 20 along the side walls of the semiconductor chip 20. A plurality of second pads 26 may be on the upper surface of the semiconductor chip 20, in which the second pads 26 are arranged inside each side wall of the semiconductor 20, adjacent to each side wall thereof, and along each side wall thereof. In addition, the first pads 14 and the second pads 26 may be electrically connected to each other through conductive lines 30, respectively. The conductive line 30 may be formed along the side wall of the semiconductor chip 20, so the conductive line 30 may be also referred to as a side wall wiring, a side wiring, or a side interconnection.

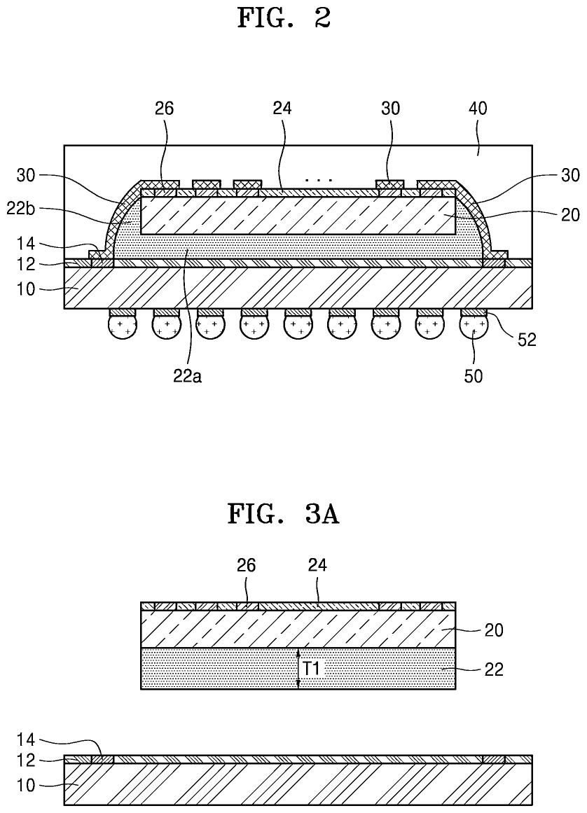

FIG. 2 is a cross-sectional view of a semiconductor package taken along line A-A of FIG. 1 according to some embodiments.

Referring to FIG. 2 together with FIG. 1, the upper surface of the package substrate 10 may be covered with the first electrical insulating layer 12. A plurality of open areas may be formed in the first electrical insulating layer 12, and the plurality of first pads 14 may be formed and exposed within the plurality of open areas, respectively. In addition, a plurality of external connection terminals 50 may be formed on a lower surface of the package substrate 10 with a plurality of lower pads 52 therebetween, respectively.

The first pad 14 formed on the upper surface and the lower pad 52 formed on the lower surface of the package substrate 10 may be electrically connected to each other, through a plurality of conductive inner wirings (not shown) horizontally formed in the inside of the package substrate 10 and a plurality of conductive plugs (not shown) that vertically connect the plurality of conductive inner wirings to each other. The first pad 14 and the lower pad 52 may include a conductive material, for example, a metal such as Al, Cu, Ag, Ta, Ti, W, Ni, and Au, and the like, or an alloy thereof, but is not limited thereto. Alternatively, the first pad 14 and the lower pad 52 may include stainless steel or beryllium copper. For example, the first pad 14 and the lower pad 52 may be exposed parts formed by coating the upper and lower surfaces of the package substrate 10 with copper foil, forming the first electrical insulating layer 12 thereon, and removing and exposing parts of the first electrical insulating 12 through a patterning process. The first electrical insulating layer 12 may include a solder resist layer.

The package substrate 10 may include a rigid material or a soft material. The package substrate 10 may be, for example, a printed circuit board (PCB). However, the package substrate 10 according to aspects of the inventive concept is not limited thereto, and may include all kinds of substrates that may support and package the semiconductor chip 20 formed thereon. On the other hand, it may also be referred to as the printed circuit board, including the package substrate 10, and the first pad 14 and the first electrical insulating layer 12 formed on the upper surface and the lower pad 52 formed on the lower surface of the package substrate 10 shown in FIG. 2. In some embodiments, a lead frame may also be used as the package substrate 10.

The external connection terminal 50 attached to the lower surface of the package substrate 10 may be attached to the lower pad 52, for example. The external connection terminal 50 may include, for example, a solder ball or a solder bump. Alternatively, the external connection terminal 50 may be, for example, a form of a lead or a pin. The semiconductor package may be electrically connected to an external electronics through the external connection terminal 50.

The semiconductor chip 20 may be mounted over the package substrate 10 with adhesive layers 22a and 22b therebetween. A second electrical insulating layer 24 may be formed on an upper surface of the semiconductor chip 20. In addition, a plurality of open areas may also be formed in the second electrical insulating layer 24, and a plurality of second pads 26 may be formed within the plurality of open areas, respectively. The second pads 26 may be electrically connected to the first pads 14 formed on the upper surface of the package substrate 10 through conductive lines 30. A sealing member 40 may be formed on the package substrate 10, to entirely seal the semiconductor chip 20 from an external environment. For example, the sealing member 40 may include an epoxy mold compound (EMC).

The semiconductor chip 20 may include a semiconductor substrate. The semiconductor substrate may include, for example, a silicon (Si) substrate, a germanium (Ge) substrate, and a SiGe substrate. In addition, the semiconductor substrate may include a compound semiconductor, such as silicon carbide (SiC), gallium arsenide (GaAs), indium arsenide (InAs), indium phosphide (InP), and the like. Alternatively, the semiconductor substrate constituting the semiconductor chip 20 may be a silicon on insulator (SOI) type substrate. The semiconductor chip 20 may include a semiconductor device including a plurality of individual devices. The plurality of individual devices may include various microelectronic devices, for example, such as metal oxide semiconductor field effect transistor (MOSFET), complementary MOS (CMOS) transistor, system large scale integration (system LSI), CMOS image sensor (CIS), micro electro mechanical system (MEMS), active device, and passive device, and the like.

On the other hand, the semiconductor chip 20 may be, for example, a memory semiconductor chip. The memory semiconductor chips may include, for example, a volatile memory semiconductor chip such as dynamic random access memory (DRAM), and static random access memory (SRAM), and a non-volatile memory semiconductor chip such as phase-change random access memory (PRAM), magnetoresistive RAM (MRAM), ferroelectric RAM (FeRAM), and resistive RAM (RRAM), and the like. In addition, the semiconductor chip 20 may be a non-memory semiconductor chip.

The first electrical insulating layer 12 and the second electrical insulating layer 24 may include the same insulating material or may include different insulating materials. For example, the first electrical insulating layer 12 and the second electrical insulating layer 24 may include photosensitive polyimide (PSPI) or photo imageable dielectric (PID).

The adhesive layer may include a first adhesive layer 22a between the package substrate 10 and the semiconductor chip 20 and a second adhesive layer 22b formed along the side walls of the semiconductor chip 20. In some embodiments, the first adhesive layer 22a and the second adhesive layer 22b may include the same adhesive material. The first adhesive layer 22a and the second adhesive layer 22b may be formed from a resin-type adhesive and may be formed from a non-conductive material that has fluidity due to heat and externally applied force.

The first adhesive layer 22a and the second adhesive layer 22b may be a die attach film (DAF), and the DAF may be attached to a lower surface of the semiconductor chip 20 for a subsequent die attach process (or a die attach pressing process). During the die attach process, the die attach film of liquid resin may bleed in X, Y, and Z directions around the side wall of the semiconductor chip 20. In some embodiments, the first adhesive layer 22a and the second adhesive layer 22b may be, for example, a non-conductive film (NCF), and in further some embodiments, the first adhesive layer 22a and the second adhesive layer 22b may be, for example, a non-conductive paste (NCP).

On the other hand, the first adhesive layer 22a and the second adhesive layer 22b may be formed integrally and continuously without a boundary therebetween. The second adhesive layer 22b may have an inclined slope extending downwardly and outwardly from the side wall of the semiconductor chip 20 toward the upper surface of the package substrate 10. As shown in FIG. 2, an exposed outer surface (i.e., a slope surface) of the second adhesive layer 22b having the inclined slope may have a convex shape. However, as long as the conductive line 30 formed in contact with the outer surface of the second adhesive layer 22b is not formed to be substantially vertical, the slope surface may have various shapes, for example, a flat shape or a concave shape. Specifically, the fact that the second adhesive layer 22b has the inclined slope means that, assuming a vertical reference line, that corresponds to a vertical line that coincides with and extends in a vertical direction (e.g., Z-direction) from the side wall of the semiconductor chip 20 to the insulating layer 12, a horizontal distance between the vertical reference line and an outermost and lowermost end of the second adhesive layer 22b that contacts the first electrical insulating layer 12 may be greater than a horizontal distance between the vertical reference line and an upper end of the second adhesive layer 22b contacting the side wall of the semiconductor chip 20.

On the other hand, in some embodiments, an inclination angle of the inclined slope of the second adhesive layer 22b may not preferably exceed, for example, about 45 degrees. The inclination angle of the inclined slope refers to an angle between the vertical reference line and an extension line of the outer surface of the second adhesive layer 22b having the inclined slope. When the inclination angle of the inclined slope exceeds, for example, about 45 degrees, a size of the semiconductor package may undesirably increase. On the other hand, when the inclination angle approaches zero, the conductive line 30 formed along the outer surface of the second adhesive layer 22b may be almost vertically formed, so during a curing process after the formation of the conductive line 30, the conductive line 30 formed vertically may shrink, or a crack may occur in the conductive line 30 due to concentration of stress. Thus, the inclination angle of the inclined slope may preferably be in a range of about 2 degrees to about 45 degrees, such as about 5 to about 40 degrees, about 10 degrees to about 30 degrees, or about 15 degrees to about 25 degrees.

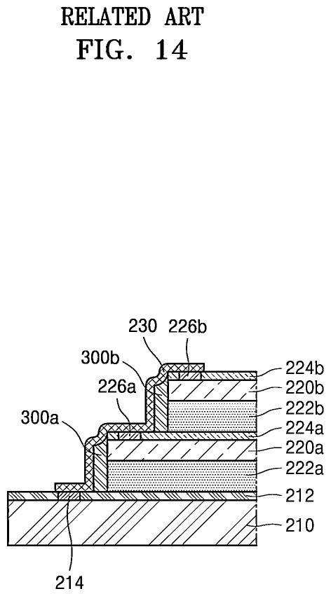

FIG. 14 is a cross-sectional view showing a portion of a conventional semiconductor package in the related art.

Referring to FIG. 14, a plurality of semiconductor chips 220a and 220b are stacked on a package substrate 210 in a step shape. A first electrical insulating layer 212 is formed on an upper surface of the package substrate 210, and a plurality of second electrical insulation layers 224a and 224b are formed on the plurality of semiconductor chips 220a and 220b, respectively. A plurality of adhesive layers 222a and 222b are formed between the package substrate 210 and the semiconductor chip 220a located at a lowermost position among the plurality of semiconductor chips 220a and 220b, and between the plurality of semiconductor chips 220a and 220b, respectively. In addition, a first pad 214 is formed on the package substrate 210, and second pads 226a and 226b are formed on the plurality of semiconductor chips 220a and 220b, respectively. The first pad 214 and the second pads 226a and 226b are electrically connected to each other through the conductive line 230. On the other hand, side wall insulation layers 300a and 300b are formed along side walls of the plurality of semiconductor chips 220a and 220b and the adhesive layers 222a and 222b attached to lower surfaces thereof, respectively.

As shown in FIG. 14, in the conventional semiconductor package, in order to insulate a semiconductor substrate (not shown), for example, a silicon substrate (not shown) formed in the semiconductor chips 220a and 220b, at least a portion of which may be exposed to the side walls of the plurality of semiconductor chips 220a and 220b, from the conductive line 230, side wall insulating layers 300a and 300b are formed on the side walls of the semiconductors 220a and 220b and the adhesive layers 222a and 222b using separate deposition and etching processes. The side wall insulating layers 300a and 300b are formed on the side walls of the plurality of semiconductor chips 220a and 220b and the side walls of adhesive layers 222a and 222b, respectively with an approximately uniform thickness, thereby being formed in a vertical direction (i.e., Z-direction) perpendicular to the upper surface of the package substrate 210. On the other hand, the conductive line 230 is formed on vertical surfaces of the side wall insulating layers 300a and 300b, and thus the conductive line 230 is also formed in the vertical direction perpendicular to the upper surface of the package substrate 210.

After the formation of the conductive line 230, the curing process for curing the conductive line 230 is usually performed. At this time, the conductive line 230 formed in the vertical direction may shrink, resulting in one or more cracks in the conductive line 230. In addition, even though cracks may not be generated in the conductive line 230 formed in the vertical direction during the curing process, when the semiconductor package is used for a long time, the stress may be concentrated on the conductive line 230 formed in the vertical direction, which may become a location of cracks.

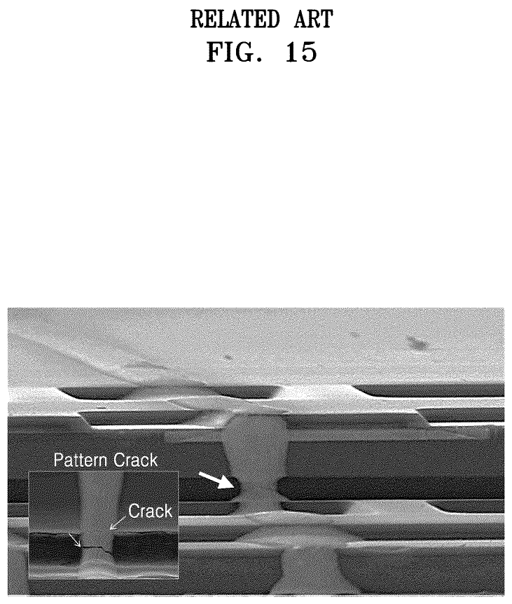

FIG. 15 is an image showing the occurrence of a crack in a conductive line in a conventional semiconductor package in the related art. An enlarged image of FIG. 15 clearly shows that the crack was generated in the conductive line, which was formed in the vertical direction on the upper surface of a package substrate.

As illustrated in FIG. 2, the second adhesive layer 22b 2 may be formed to surround the side wall of the semiconductor chip 20. For example, as shown in FIG. 1, the second adhesive layer 22b may be formed on the four side walls of the semiconductor chip 20 in a quadrangle shape. Referring again to FIG. 2, the semiconductor chip 20 may include a first side wall (SW1, as shown in FIG. 1) and a second side wall (SW2, as shown in FIG. 1) opposing to the first side wall SW1, and the second adhesive layer 22b formed on outer sides of each of the first side wall SW1 and the second side wall SW2 may be symmetrically formed.

In addition, the second adhesive layer 22b may be formed in contact with the side walls of the semiconductor chip 20. The side walls of the semiconductor chip 20 may be completely electrically insulated. However, in some embodiments, a semiconductor layer, such as a silicon substrate, or a portion of an electrical conductive layer constituting the semiconductor chip 20 may comprise the side walls of the semiconductor chip 20. In this case, the second adhesive layer 22b may completely cover the side walls of the semiconductor chip 20 across the entire side walls of the semiconductor chip 20. Additionally, the second adhesive layer 22b may maintain the slope surface with the inclined slope as described above, irrespective of whether or not an insulation layer (not shown), different from the second adhesive layer 22b, is included between at least a portion of the side walls of the semiconductor chip 20 and the second adhesive layer 22b. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting,” “in contact with,” or “contact” another element, there are no intervening elements present at the point of contact.

In addition, the second adhesive layer 22b may contact the first electrical insulating layer 12 on the package substrate 10. However, as long as the second adhesive layer 22b may maintain the slope surface with the inclined slope as described above, an insulation layer (not shown) different from the adhesive layer 22b may be further included between the first electrical insulating layer 12 and the second adhesive layer 22b.

In addition, the outermost and lowermost end of the second adhesive layer 22b may be preferably formed not to cover the first pad 14 formed on the upper surface of the package substrate 10. For example, in order to sufficiently secure a contact area between the conductive line 30 and the first pad 14, it is preferable that a horizontally extending or protruding end of the second adhesive layer 22b, that is, the outermost and lowermost end of the second adhesive layer 22b, may not invade (e.g., cover) the first pad 14.

On the other hand, considering that a semiconductor layer (not shown) such as a silicon substrate, or a portion of an electrically conductive layer may be exposed to the side walls of the semiconductor chip 20, the second adhesive layer 22b may cover the entire side walls of the semiconductor chip 20 and may even cover a portion of the upper surface of the semiconductor chip 20 adjacent to the side walls of the semiconductor chip 20. In a case of embodiments where the side walls of the semiconductor chip 20 is completely insulated, the second adhesive layer 22b may cover only a portion of the side walls of the semiconductor chip 20. For example, an upper end of the second adhesive layer 22b may contact the semiconductor chip 20 at a mid-height of the semiconductor chip 20, for example, between an upper end and a lower end of the semiconductor chip 20.

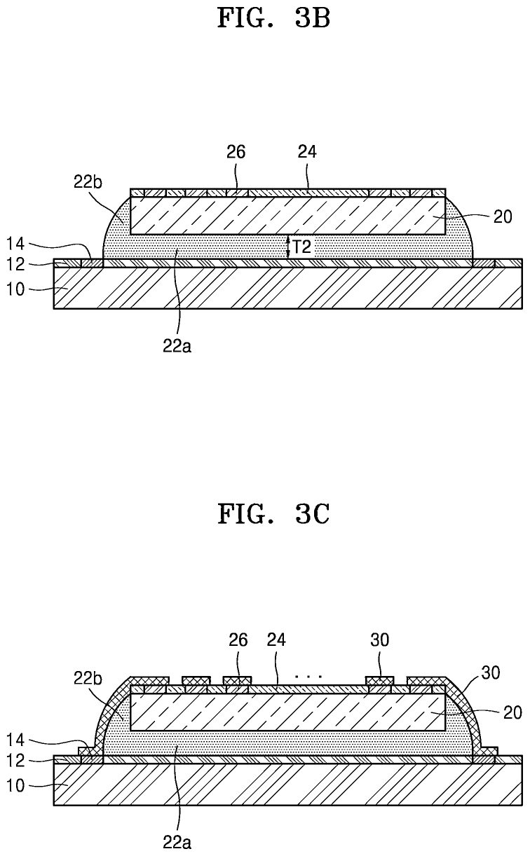

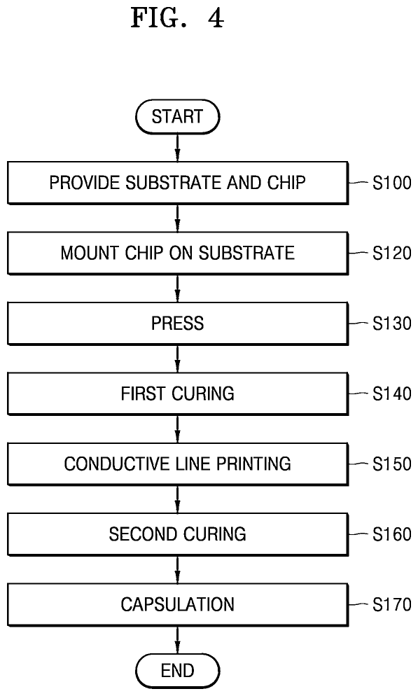

FIGS. 3A to 3C are cross-sectional views sequentially showing a manufacturing process of the semiconductor package of FIG. 2, taken along line A-A in FIG. 1, according to some embodiments. FIG. 4 is a flow chart sequentially describing a manufacturing process of the semiconductor package of FIG. 2 according to some embodiments. FIGS. 3A to 3C and 4 show the manufacturing process of the semiconductor package in which one semiconductor chip 20 may be formed on the package substrate 10.

Referring to FIG. 3A together with FIG. 4, the package substrate 10 and the semiconductor chip 20 may be provided (S100). The package substrate 10 may be a printed circuit board, but is not limited thereto. The package substrate 10 may support the semiconductor chip 20 mounted thereon, and may function to electrically connect electronic devices formed in the semiconductor chip 20 to external electronics (not shown). In order to perform this function, internal wirings (not shown) and conductive plugs (not shown) connecting the internal wirings to each other may be formed inside the package substrate 10. The first electric insulating layer 12 may be formed on the upper surface of the package substrate 10, and the first pads 14 may be formed on the package substrate 10 and with open areas of the first electrical insulating layer 12 (i.e., areas where the first electrical insulating layer 12 does not cover the package substrate 10). The first pads 14 may be connected to the internal wirings formed on the surface or inside of the package substrate 10. The first electrical insulating layer 12 and the second electrical insulating layer 24 formed on the semiconductor chip 20 may include PSPI or PID.

The semiconductor chip 20 may be obtained through a sawing process of a semiconductor wafer that yields individual chip units. An adhesive layer 22 may be applied to the lower surface of the semiconductor chip 20. A second electrical insulating layer 24 may be formed on the upper surface of the semiconductor chip 20. In addition, a plurality of open areas (i.e., areas exposing portions of the upper surface of the semiconductor chip 20) may also be formed in the second electrical insulating layer 24, and the plurality of second pads 26 may be formed within the plurality of open areas, respectively. The semiconductor chip 20 may include a semiconductor substrate. The semiconductor substrate may include, for example, a silicon substrate, a germanium substrate, and a SiGe substrate, and the like. In addition, the semiconductor substrate may include compound semiconductors such as SiC, GaAs, InAs, and InP, and the like. On the other hand, the semiconductor chip 20 may be a memory semiconductor chip or a non-memory semiconductor chip.

The adhesive layer 22 may be applied to the lower surface of the semiconductor chip 20 with a predetermined thickness T1. The adhesive layer 22 may use, for example, a resin-type adhesive, and may be formed from a non-conductive material that has fluidity by heat and a force applied from the outside. The adhesive layer 22 must be able to perform an adhesive function, and may include, for example, an epoxy-based adhesive, an acrylic-based adhesive, a silicone-based adhesive, or a urethane-based adhesive, and the like. In some embodiments, the epoxy-based adhesive with excellent thermal curability may be preferably used. In addition, the adhesive layer 22 may be one having non-conductive properties. The adhesive layer 22 may be formed from various adhesive materials having high adhesiveness, low moisture absorptivity, appropriate mechanical property, fast thermosetting property, non-conductive property, high fluidity and wettability at a contact interface during high temperature/high pressure bonding. The adhesive layer 22 may be provided as a solid film or a liquid paste. Specifically, the adhesive layer 22 may be formed of, for example, a non-conductive film or a non-conductive paste.

Subsequently, referring to FIGS. 3B and 4 together, the semiconductor chip 20 having the adhesive layer 22 formed on the lower surface thereof may be mounted on the package substrate 10 (S120). The mounting of the semiconductor chip 20 may be performed by a die bonder, and after sawing a semiconductor wafer in chip units (i.e., semiconductor chips), the die bonder may pick up a selected semiconductor chip and then may correctly mount the selected semiconductor chip in a predetermined position on the package substrate 10. Subsequently, a die attach pressing process may be performed on the semiconductor chip 20 aligned in a predetermined position of the package substrate 10 (S130). Due to the pressure applied from an upper portion of the semiconductor chip 20 through the die attach pressing process, the adhesive layer 22 may bleed toward the side walls of the semiconductor chip 20 to form a fillet around the side walls of the semiconductor chip 20.

As shown in FIG. 3B, the adhesive layer 22 to be pressed may be pushed out from a space between the semiconductor chip 20 and the package substrate 10, then the adhesive layer 22 may be pushed out toward the outside of the side walls of the semiconductor chip 20, and then may be formed on the side walls of the semiconductor chip 20 while being pushed upward along the side walls of the semiconductor chip 20 due to its wettability characteristics at the contact interface thereof. At the same time, a portion of the adhesive layer 22 may be formed on the upper surface of the package substrate 10 (specifically, an upper surface of the first electrical insulating layer 12 formed on the upper surface of the package substrate 10) while being pushed away from the side walls of the semiconductor chip 20). Hereinafter, after the die attach pressing process, the adhesive layer 22 shown in FIG. 3A may be divided into and referred to a first adhesive layer 22a and a second adhesive layer 22b, wherein the first adhesive layer 22a may be the adhesive layer existing in the space between the semiconductor chip 20 and the package substrate 10, and the second adhesive layer 22b may be the adhesive layer existing outside the vertical reference line vertically extending along the side walls of the semiconductor chip 20.

The first adhesive layer 22a and the second adhesive layer 22b may be formed from the same adhesive layer 22, so the first adhesive layer 22a and the second adhesive layer 22b may include the same adhesive material and may be formed continuously without the formation of boundary therebetween. In addition, a uniform pressing force may be applied across an entire surface area of the semiconductor chip 20 in the die attach pressing process, so the second adhesive layer 22b may be formed symmetrically at opposing positions. For example, when applied to the plan view of FIG. 1, the second adhesive layer 22b may be pushed out along four sides of the semiconductor chip 20, that is, along the side walls of the semiconductor chip 20 and may be formed in the same shapes. Thus, the second adhesive layer 22b may be symmetrically formed to each other on a first side wall SW1 of the semiconductor chip 20 and the second side wall SW2 opposing the first side wall SW1. For example, the shape and slope of the second adhesive layer 22b formed along the first side wall SW1 may be the same as the shape and slope of the second adhesive layer 22b formed along the first side wall SW2.

As shown in FIG. 3B, the second adhesive layer 22b may be formed in a spacer shape along the side walls of the semiconductor chip 20. That is, the outer surface of the second adhesive layer 22b may have a slope having a predetermined inclination angle. In FIG. 3B, the slope surface may have a convex shape that rises above a flat surface, but is not limited thereto. The slope surface may maintain an inclined flat surface or have a concave shape that sags below the flat surface. Assuming a point where a top of the second adhesive layer 22b contacts the side wall of the semiconductor chip 20 as a vertex, the inclination angle of the slope may be defined as an angle between the vertical reference line, as discussed above, and an extension line of the slope surface, wherein the extension line of the slope surface extends between the vertex and a contacting point at which the outermost and lowermost end of the second adhesive layer 22b contacts the first electrical insulating layer 12 on the package substrate 10. The fact that the outer surface of the second adhesive layer 22b may have a slope with a predetermined inclination angle means that a horizontal distance between a contact point (e.g., first contact point) of the vertical reference line with the first electrical insulating layer 12 and a contact point (e.g., second contact point) of the outermost and lowermost end of the second adhesive layer 22b with the first electrical insulating layer 12, may be greater than a horizontal distance between the vertical reference line and the upper end of the second adhesive layer 22b. This may be significant when an insulating layer different from the second adhesive layer 22b is formed between the side wall of the semiconductor chip 20 and the second adhesive layer 22b.

On the other hand, in some embodiments, the inclination angle may not preferably exceed about 45 degrees. As the inclination angle increases, a horizontal area occupied by the second adhesive layer 22b may also increase, which may be contrary to the miniaturization of the semiconductor package. On the other hand, as the inclination angle increases, a distance over which the second adhesive layer 22b protrudes and extends in the horizontal direction on the first insulating layer 12 may also increase, so the second adhesive layer 22b may undesirably extend above and invade (e.g., cover) the first pad 14. On the other hand, in some embodiments, it may be preferable that the inclination angle is not at least zero. The smaller the inclination angle, the closer the outer surface of the second adhesive layer 22b to the vertical line. Thus, as described above with respect to FIGS. 14 and 15, the possibility of cracks occurring in the conductive line formed along the outer surface of the second adhesive layer 22b may increase. Thus, the inclination angle of the slope surface may be trade-off in view of the two aspects above. In some embodiments, the inclination angle may be in the range of about 2 degrees to about 45 degrees, about 10 degrees to about 30 degrees, or about 15 degrees to about 20 degrees.

As described above with respect to FIG. 2, a separate insulating layer (not shown) different from the second adhesive layer 22b may be disposed between the side wall of the semiconductor chip 20 and the second adhesive layer 22b. Even in this case, one of ordinary skill in the art will recognize that the outer surface of the second adhesive layer 22b may have a slope with the above-described characteristics. In addition, a separate insulating layer (not shown) different from the second adhesive layer 22b may also be formed between the second adhesive layer 22b and the first electrical insulating layer 12. Even in this case, one of ordinary skill in the art will recognize that the outer surface of the second adhesive layer 22b may have the slope with the above-described characteristics.

On the other hand, in the embodiment of FIG. 3B, an upper end height of the second adhesive layer 22b is shown to match an upper end height of the semiconductor chip 20. Aspects of the inventive concept are not limited thereto, and the upper end height of the second adhesive layer 22b may be greater than or equal to the upper end height of the semiconductor chip 20, or less than or equal to that of the semiconductor chip 20. In some embodiments, as discussed above, a semiconductor layer, such as a silicon substrate, or a portion of an electrical conductive layer constituting the semiconductor chip 20 may comprise the side walls of the semiconductor chip 20. When an insulating layer is formed on the side walls of the semiconductor chip 20, such that the semiconductor layer and/or electrical conductive layer of the semiconductor chip 20 are covered (i.e., not exposed), the upper end height of the second adhesive layer 22b may be less than or equal to that of the semiconductor chip 20. On the other hand, when an insulating layer is not formed on the side walls of the semiconductor chip 20, such that the semiconductor layer and/or electrical conductive layer of the semiconductor chip 20 are not covered (i.e., exposed), the upper end height of the second adhesive layer 22b may be formed to be greater than or equal to that of the semiconductor chip 20.

The upper end height of the second adhesive layer 22b and the distance from the vertical reference line coinciding with the side walls of the semiconductor chip 20 to the outermost and lowermost end of the second adhesive layer 22b may need to be precisely controlled in terms of securing the insulation of the outer surface of the second adhesive layer 22b, securing the slope of the outer surface of the second adhesive layer 22b, and preventing invasion (i.e., covering) of the first pad 14 by the second adhesive layer 22b, or in terms of miniaturization of the semiconductor package.

When a volume (i.e., thickness T1×width W×length L) of the adhesive layer 22 formed on the lower surface of the semiconductor chip 20 is not significantly changed through the die attach pressing process, the volume of the adhesive layer 22 may be the same as a sum of a volume of the adhesive layer 22a and a volume of the second adhesive layer 22b, wherein T1>T2. Considering the above, the die attach pressing process may be performed while heating to a predetermined temperature. As a temperature of the adhesive layer 22 increases, a viscosity of the adhesive layer 22 may decrease, a fluidity thereof may increase, and the wettability thereof at the contact interface may also increase. Therefore, in the die attach pressing process, in addition to a magnitude of the pressing force applied from the outside, a heating temperature applied to the adhesive layer may also be an important variable. The pressing force and the heating temperature conditions may vary depending on the type of the adhesive layer 22. For example, when using an epoxy-based adhesive in the form of a liquid resin as the adhesive layer 22, the heating temperature condition may be in the range of about 100° C. to about 200° C., or about 100° C. to about 150° C.

Subsequently, referring to FIGS. 3B and 4, when the die attach pressing process is terminated, a first curing process may be performed for the structural stability of the first adhesive layer 22a and the second adhesive layer 22b (S140).

Subsequently, referring to FIGS. 3C and 4, a conductive line printing process for forming the conductive line 30 that electrically connects the first pad 14 exposed on the package substrate 10 to the second pad 26 exposed on the semiconductor chip 20 may be performed (S150). The conductive line printing process may be performed while flowing a molten conductive material from an upper side to a lower side, or may be performed in a roll-printing method, but is not limited thereto, and may be performed through various technologies known to one of ordinary skill in the art. The conductive material for the conductive line may be the same as those described above with respect to FIG. 2.

Subsequently, referring to FIGS. 3C and 4, when the conductive line printing process is terminated, a second curing process may be performed for the structural stability of the conductive line 30 (S160). Next, an encapsulation process may be performed over the package substrate 10 using a sealing member 40 (shown in FIG. 2) to protect and electrically insulate the semiconductor chip 20 and the conductive line 30 from the external environment (S170). As the sealing member 40, EMC may be used, for example. The encapsulation process may be performed through various technologies known to one of ordinary skill in the art. When the encapsulation process is terminated, the external connection terminal 50 such as a solder ball may be formed on the exposed lower pad 52 on the lower surface of the package substrate 10, thereby completing the semiconductor package shown in FIG. 2. In addition to the solder ball, the external connection terminal 50 may be formed in the form of a solder bump, a lead of a lead frame, or a pin, and the like.

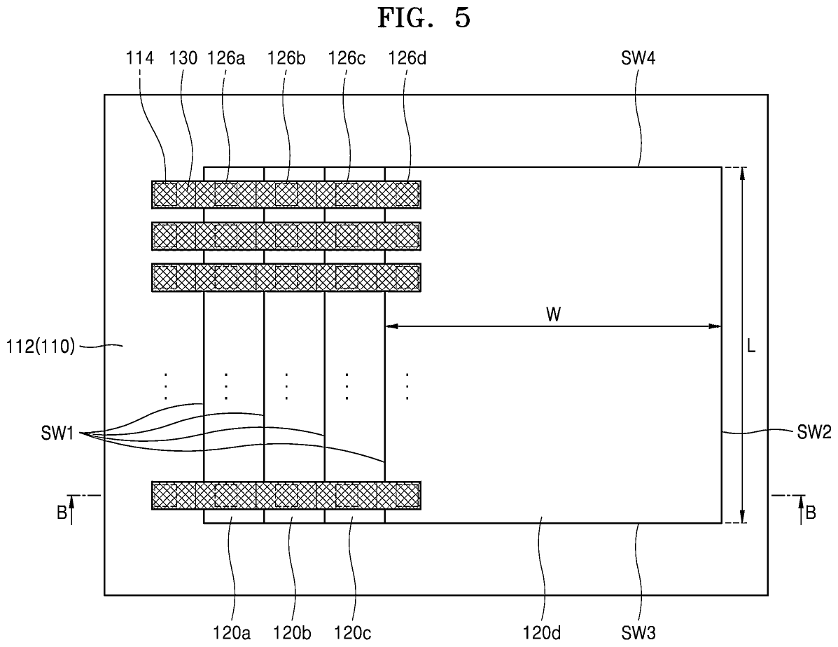

FIG. 5 is a simplified plan view of a semiconductor package according to some embodiments. The semiconductor package of the embodiment shown in FIG. 5 is different from that of the embodiment shown in FIG. 1 in that the semiconductor package in FIG. 5 relates to the semiconductor package in which a plurality of semiconductor chips are stacked on the package substrate. Descriptions that overlap the description of the semiconductor package shown in FIG. 1 will be omitted as much as possible.

Referring to FIG. 5, a semiconductor package may include a plurality of a quadrangle semiconductor chips 120a, 120b, 120c, and 120d arranged in a central region of a quadrangle package substrate 110. FIG. 5 shows that a first electrical insulating layer 112 may be formed on an upper surface of the package substrate 110, and a plurality of second electrical insulating layers 124a, 124b, 124c, and 124d may be respectively formed on upper surfaces of the plurality of semiconductor chips 120a, 120b, 120c, and 120d. The plurality of semiconductor chips 120a, 120b, 120c, and 120d may have the same size. Here, the fact that the plurality of semiconductor chips 120a, 120b, 120c, and 120d have the same size means that they have the same surface area. Specifically, each of the plurality of semiconductor chips 120a, 120b, 120c, and 120d may have a first length L in a length direction (e.g., a first horizontal direction or X-direction) and may have a first width W in a width direction (e.g., a second horizontal direction or Y-direction). On the other hand, the thicknesses of the plurality of semiconductor chips 120a, 120b, 120c, and 120d may be all the same, partially the same, partially different, or all different.

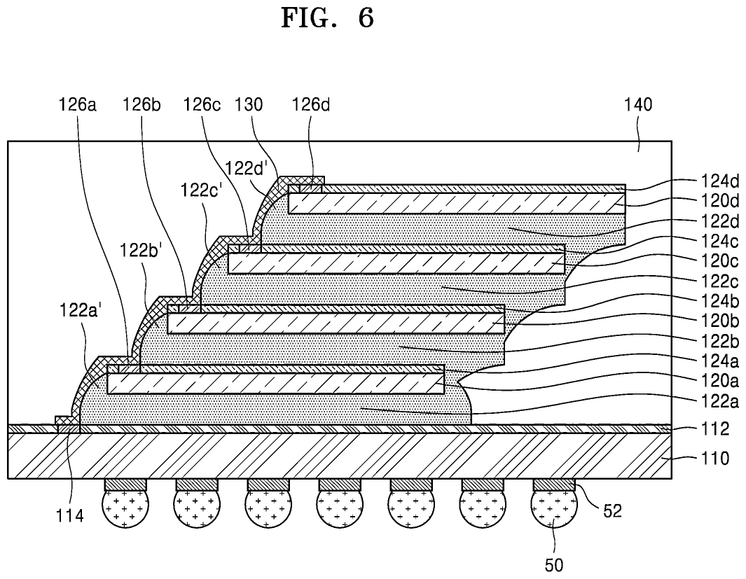

On the upper surface of the package substrate 110, the plurality of semiconductor chips 120a, 120b, 120c, and 120d may be formed so that any two opposing side walls thereof (e.g., third side walls SW3 and fourth side walls SW4 opposing the third side walls SW3) are vertically aligned with each other. In addition, one group of side walls (e.g., a plurality of first side walls SW1, on the left side in the cross sectional view of FIG. 6) between the third and fourth side walls SW3 and SW4 that are vertically aligned with each other may be stacked in a step shape. As a result, another group of side walls (e.g., a plurality of second side walls SW2 on the right side in the cross-sectional view of FIG. 6) may be stacked in an inverse-step shape. A plurality of first pads 114 may be arranged on the package substrate 110, so that the first pads 114 are adjacent to the first side wall SW1 of the first semiconductor chip 120a arranged in the lowermost position among the plurality of semiconductor chips 120a, 120b, 120c, and 120d. In addition, a plurality of second pads 126a, 126b, 126c, and 126d may be arranged on upper surfaces of the plurality of semiconductor chips 120a, 120b, 120c, 120d, respectively so that the plurality of second pads 126a, 126b, 126c, and 126d respectively correspond to the plurality of first pads 114 and are respectively adjacent to the first side walls of the plurality of semiconductor chips 120a, 120b, 120c, 120d. The plurality of first pads 114 and the plurality of second pads 126a, 126b, 126c, and 126d are electrically connected to each other through a plurality of conductive lines 130, respectively.

FIG. 6 is a cross-sectional view of a semiconductor package taken along line B-B of FIG. 5 according to some embodiments.

Referring to FIG. 5 together with FIG. 6, the upper surface of the package substrate 110 may be covered with the first electrical insulating layer 112. A plurality of open areas may be formed in the first electrical insulating layer 112, and the plurality of first pads 114 may be formed and exposed within the plurality of open areas, respectively. In addition, the plurality of external connection terminals 50 may be attached to a lower surface of the package substrate 110 with the plurality of lower pads 52 therebetween, respectively. FIG. 6 shows an embodiment in which four semiconductor chips are stacked, but aspects of the inventive concept are not limited thereto, and fewer or more semiconductor chips may be stacked.

The semiconductor chips 120a-120d may be mounted on the package substrate 110 with adhesive layers 122a-122d therebetween, respectively. A sealing member 140 may be formed on the package substrate 110, to entirely seal the semiconductor chips 120a-120 from an external environment. The first electrical insulating layer 112 and second electrical insulating layers 124a-124d may include the same insulating material or may include different insulating materials. For example, the first electrical insulating layer 112 and the second electric insulating layer 124a-124 may include PSPI or PID.

The adhesive layers 122a-122d may be hereinafter referred to separately as a first adhesive layer 122a-122d and a second adhesive layer 122a′-122d′, wherein the first adhesive layer 122a-122d may be between the package substrate 110 and the first semiconductor chip 120a and between the semiconductor chips 120a-120d, and the second adhesive layer 122a′-122d′ may be formed along the first side walls SW1 of the semiconductor chips 120a-120d. In some embodiments, the first adhesive layer 122a-122d and the second adhesive layer 122a′-122d′ may include the same adhesive material. The first and second adhesive layer may use, for example, a resin-type adhesive, and may be formed from a non-conductive material that has fluidity by heat and the force applied from the outside.

The first adhesive layers 122a-122d may be attached to lower surfaces of each semiconductor chips 120a-120d, and when the subsequent die attach pressing process is performed, a liquid resin may bleed onto the first side walls SW1 of the semiconductor chips 120a-120d. The adhesive layer may include a non-conductive adhesive, for example, NCF or NCP.

As a result of the die attach pressing process, each of the second adhesive layers 122a′-122d′ may have an inclined slope on each of the first side walls SW1 of the semiconductor chips 120a-120d formed in the step shape, in which the inclined slope extends outwardly and downwardly from each of the first side walls SW1 of the semiconductor chips 120a-120d towards the upper surface of the package substrate 110. In FIG. 6, a slope surface of the second adhesive layers 122a′-122d′ having the inclined slope is shown in a convex shape, but is not limited thereto, the slope surface may be a flat shape or a concave shape.

On the other hand, as described above with respect to embodiments of FIG. 2, an inclination angle of the slope surface of the second adhesive layer 122a′-122d′ may be preferably neither too large nor too small for the same reason. The inclination angle may not preferably exceed about 45 degrees, for example, and may be in the range of about 2 degrees to about 45 degrees, such as about 5 degrees to about 40 degrees, about 10 degrees to about 30 degrees, or about 15 degrees to about 25 degrees.

Referring again to FIGS. 5 and 6, each of the second adhesive layers 122a′-122d′ formed on the first side wall SW1 of each of the semiconductor chips 120a-120d where the first side walls SW1 of the semiconductor chips 120a-120d are arranged in the step shape, may have the slope surface, wherein the second adhesive layers 122a′-122d′ respectively formed in an upper position and a lower position are separated from each other. However, the adhesive layers formed on other side walls (e.g., the second side wall SW2, the third side wall SW3, and the fourth side wall SW4) of the semiconductor chips 120a-120d excluding the first side wall SW1 may be formed in a shape that flow down along each side wall of the semiconductor chips 120a-120d. In this case, the adhesive layers flowing down along the other side walls SW2, SW3, and SW4 of the semiconductor chips 120a-120d may be formed integrally while contacting each other. In other embodiments, when one or more other side walls of the semiconductor chips 120a-120d except the first side wall SW1 are arranged in the step shape, the adhesive layers in the corresponding side walls may also have the slope surface along the corresponding side walls of the semiconductor chips 120a-120d.

In addition, the second adhesive layer 122a′-122d′ may contact the first side wall SW1 of each semiconductor chip stacked in the step shape. In some embodiments, as discussed above, a semiconductor layer, such as a silicon substrate, or a portion of an electrical conductive layer constituting the semiconductor chips 120a, 120b, 120c, 120d may comprise the side walls of the semiconductor chips 120a, 120b, 120c, 120d. When an insulating layer is formed on the side walls of the semiconductor chips 120a, 120b, 120c, 120d, such that the semiconductor layer and/or the electrical conductive layer of the semiconductor chips 120a, 120b, 120c, 120d are covered (i.e., not exposed), the second adhesive layer 122a′-122d′ may entirely cover the corresponding first side wall SW1 of the corresponding semiconductor chips 120a, 120b, 120c, 120d. Additionally, the second adhesive layers 122a′-122d′ may maintain the slope surface with the inclined slope as described above, irrespective of whether or not an insulation layer (not shown), different from the second adhesive layers 122a′-122d′, is included between at least a portion of the side wall SW1 of the corresponding semiconductor chips 120a, 120b, 120c, 120d and the corresponding second adhesive layers 122a′-122d′.

In addition, the second adhesive layer 122a′ may contact the first electrical insulating layer 112 on the package substrate 110. However, as long as the second adhesive layer 122a′ may maintain the slope surface with the inclined slope as described above, an insulation layer (not shown) different from the second adhesive layer 122a′ may be further included between the first electrical insulating layer 112 and the second adhesive layer 122a′.

A thickness of the first adhesive layer 122a between the semiconductor chip 120a arranged at a lowermost position among the semiconductor chips 120a, 120b, 120c, 120d and the package substrate 110 may be greater than a thickness of the first adhesive layers 122b-122d between the respective plurality of semiconductor chips 120a-120d. In addition, the respective thickness of the first adhesive layers 120a-120d between the respective plurality of semiconductor chips 120a, 120b, 120c, 120d may not be equal to (i.e., may be different from) each other. For example, the respective thickness of the first adhesive layers 120a-120d between the respective plurality of semiconductor chips 120a, 120b, 120c, 120d may increase or decrease away from the package substrate 110.

As described above with respect to the semiconductor package shown in FIG. 2, each of the second adhesive layers 122a′-122d′ may entirely cover the first side wall of the corresponding semiconductor chip, and further even cover a portion of an upper surface of the corresponding semiconductor chip adjacent the first side wall SW1 of the corresponding semiconductor chip. In addition, an upper end of the second adhesive layer may only cover the first side wall of the corresponding semiconductor chip by a mid-height thereof.

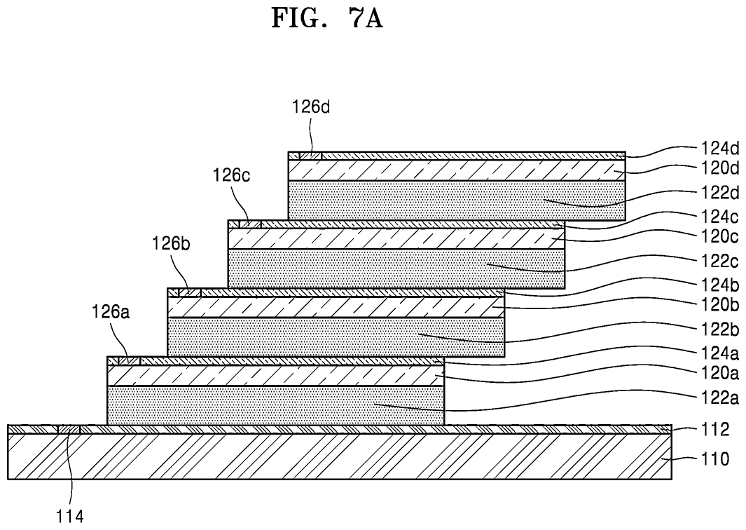

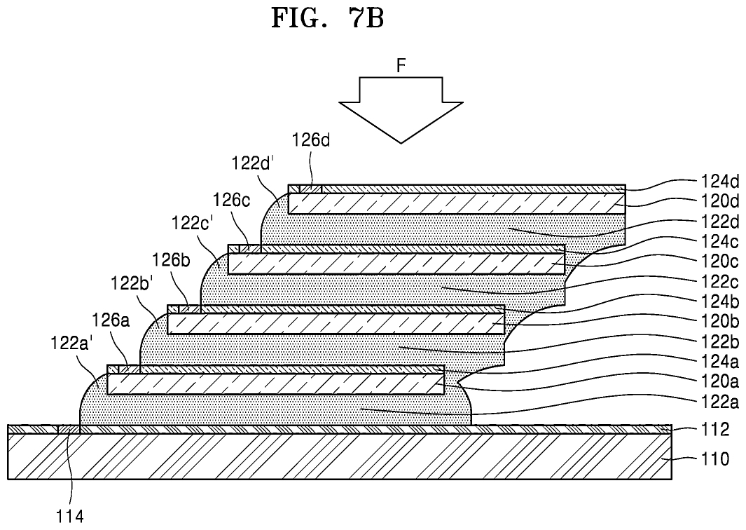

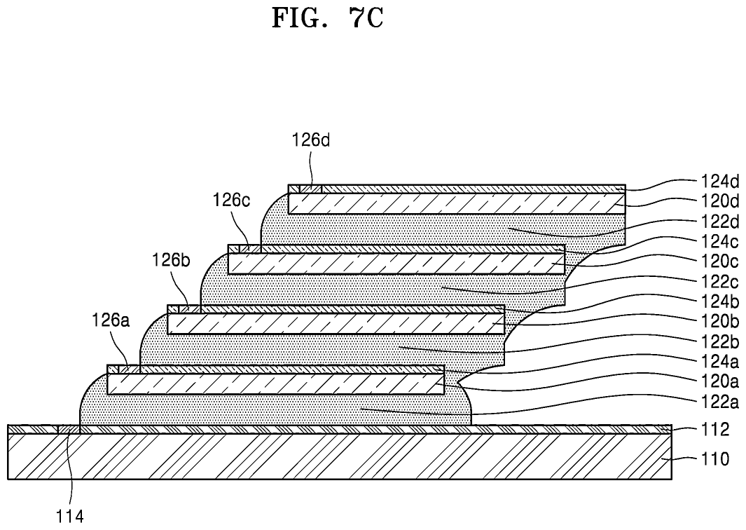

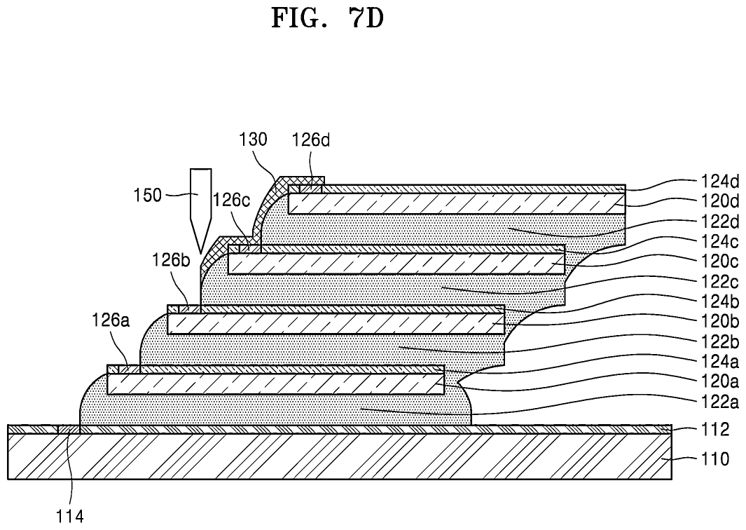

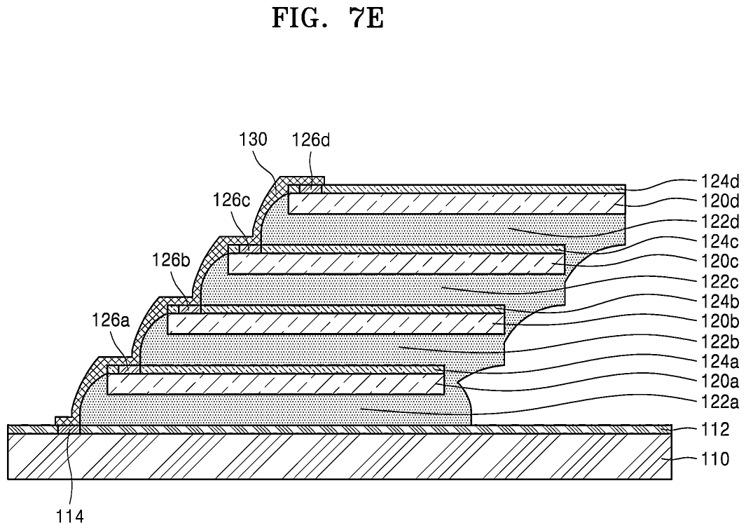

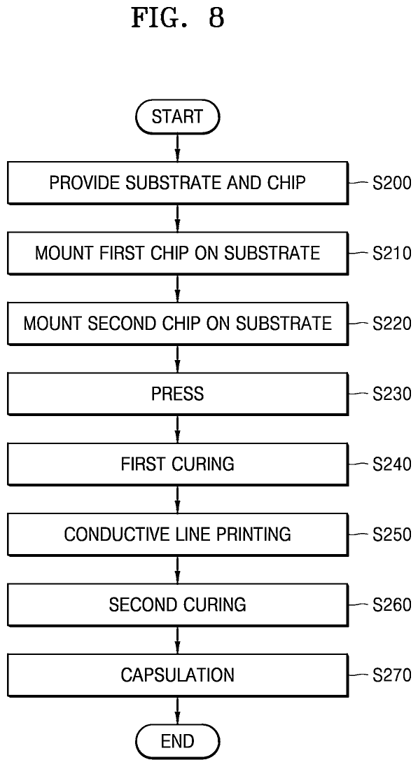

FIGS. 7A to 7E are cross-sectional views sequentially showing a manufacturing process of the semiconductor package of FIG. 6, taken along line B-B in FIG. 5, according to some embodiments. FIG. 8 is a flow chart sequentially describing a manufacturing process of the semiconductor package of FIG. 6 according to some embodiments. FIGS. 7A to 7E and 8 show the manufacturing process of a semiconductor package formed with a plurality of semiconductor chips 120a-120d having the same size on the package substrate 110. Descriptions that overlap the description of the semiconductor package shown in FIGS. 3A to 3C and 4 will be omitted as much as possible.

Referring to FIG. 7A together with FIG. 8, the package substrate 110 and a plurality of semiconductor chips 120a-120d may be provided (S200). The plurality of semiconductor chips 120a-120d may be obtained through the sawing process of a semiconductor wafer that yields individual chip units (i.e., semiconductor chips). The first adhesive layers 122a-122d may be applied to the corresponding lower surfaces of the plurality of semiconductor chips 120a-120d, respectively. The plurality of semiconductor chips 120a-120d may be obtained from the same semiconductor wafer, and the adhesive layers 122a-122d may contain the same material.

Subsequently, referring to FIGS. 7A and 8 together, the first semiconductor chip 120a formed with the adhesive layer 122a at a predetermined position on the lower surface thereof, may be mounted on the package substrate 110 (S210). Subsequently, the second through fourth semiconductor chip 120b-120d may be sequentially mounted on the first semiconductor chip 120a (S220). As shown in FIG. 6, the plurality of semiconductor chips 120a-120d may be stacked so that the first side walls SW1 of the plurality of semiconductor chips 120a-120d may be stacked in a step shape.

Subsequently, a die attach pressing process may be performed on the plurality of semiconductor chips 120a-120d aligned in predetermined positions of the package substrate 110 under a predetermined heating temperature condition (S230). The first adhesive layer 122a-122d attached to each lower surface of the plurality of semiconductor chips 120a-120d may be pushed out in a direction of each side wall of the semiconductor chips 120a-120d by a pressure applied from an upper portion of the semiconductor chips 120a-120d during the die attach pressing process. In this case, where the plurality of semiconductor chips 120a-120d are arranged in the step shape, an adhesive material may be pushed up along the first side walls SW1 of each of the semiconductor chips 120a-120d due to wettability characteristics at a contact interface. With respect to the other side walls (e.g., the second side wall SW2, the third side wall SW3, or the fourth side wall SW4) that are not arranged in the step shape, the adhesive material may flow downwardly. For example, with respect to the second side walls SW2 stacked in a reverse-step shape opposing the first side walls SW1 stacked in the step shape, the adhesive material attached to the lower surface of the semiconductor chip arranged on an upper side may flow down along the second side wall SW2 of the semiconductor chip arranged on a lower side. Thus, the adhesive layers formed on each side wall of the plurality of semiconductor chips 120a-120d may not be symmetrical.

The second adhesive layers 122a′-122d′ formed on the first side walls SW1 of the plurality of semiconductor chips 120a-120ds may have the same slope as the second adhesive layer 22b formed on the side wall of the semiconductor chip 20 shown in FIG. 2, so detailed descriptions thereof will be omitted.

With respect to each of the semiconductor chips 120a-120d, an upper end height of the second adhesive layer and a distance from a vertical reference line coinciding with the first side wall of the semiconductor chip to an outermost and lowermost end of the second adhesive layer may need to be precisely controlled in terms of securing the insulation of an outer surface of the second adhesive layer, securing the slope of the outer surface of the second adhesive layer, and preventing invasion (i.e., covering) of the first pad 114 by the second adhesive layer, or in terms of miniaturization of the semiconductor package. Temperature and pressure force conditions of the die attach pressing process may be an important variable and may vary depending on the type of adhesive.

Subsequently, referring to FIGS. 7C and 8, when the die attach pressing process is terminated, a first curing process may be performed for the structural stability of the first adhesive layers 122a-122d and the second adhesive layers second adhesive layers 122a′-122d′ (S240).

Subsequently, referring to FIGS. 7D and 8, a conductive line printing process for forming the conductive line 130 that electrically connects the first pad 114 exposed on the package substrate 110 to the second pads 126a-126d exposed on the semiconductor chips 120a-120d may be performed (S250). The conductive line printing process may be performed while flowing downwardly a conductive molten material from an upper side to a lower side through a conductive material supplier 150, or may be performed using a roll printing method.

Subsequently, referring to FIGS. 7E and 8, when the conductive line printing process is terminated, a second curing process may be performed for the structural stability of the conductive line 130 (S260). Next, an encapsulation process may be performed over the package substrate 110 using a sealing member 140 (shown in FIG. 6), for example, EMC to protect and electrically insulate the semiconductor chips 120a-120d and the conductive line 130 from the external environment (S270). When the encapsulation process is terminated, the external connection terminal 50 such as a solder ball may be formed on the exposed lower pad 52 on the lower surface of the package substrate 110, thereby completing the semiconductor package shown in FIG. 6.

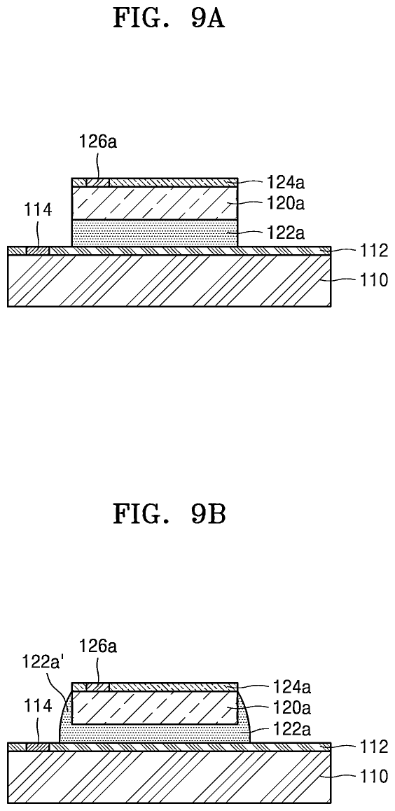

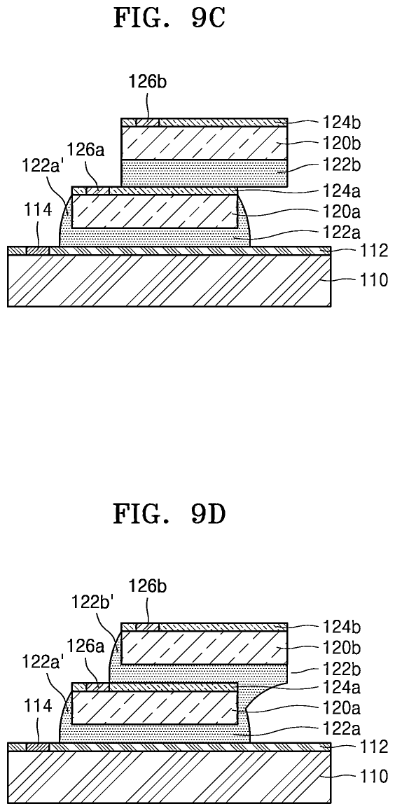

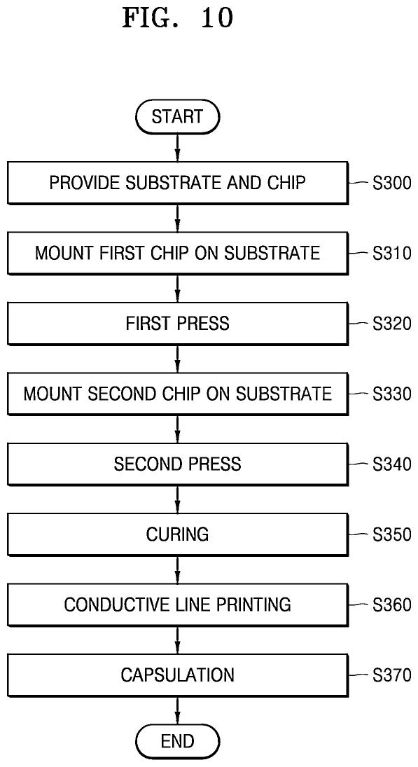

FIGS. 9A to 9D are cross-sectional views sequentially showing a manufacturing process of the semiconductor package of FIG. 6 according to some embodiments. FIG. 10 is a flow chart sequentially describing a manufacturing process of the semiconductor package of FIG. 6 according to some embodiments. The manufacturing process of the semiconductor package shown in FIGS. 9A to 9D, may be different from the manufacturing process of the semiconductor package as shown in FIGS. 7A to 7E in which all semiconductor chips are mounted on the package substrate and then the die attach pressing process is performed at once, in that the die attach pressing process may be performed one by one after mounting semiconductor chips on the semiconductor substrate one by one. In some embodiments, the semiconductor chips stacked on the package substrate may be stacked in groups of two or three semiconductor chips, and then the die attach pressing process may be performed several times (e.g., an instance of the die attach pressing process may be performed after each group of semiconductor chips are stacked). In particular, when stacking a very large number of semiconductor chips, it may be preferable to divide the die attach pressing process into several times (i.e., instances) in terms of structural stability.

Referring to FIG. 9A together with FIG. 10, a package substrate 110 and a first semiconductor chip 120a may be provided (S300). Subsequently, the first semiconductor chip 120a on which a first adhesive layer 122a is formed on a lower surface of the package substrate 110 may be mounted on a predetermined position in the package substrate 110 (S310).

Subsequently, referring to FIGS. 9B and 10, a first die attach pressing process may be performed on the first semiconductor chip 120a arranged in the predetermined position of the package substrate 110 under a predetermined temperature condition (S320). The first adhesive layer 122a may be pushed toward side walls of the semiconductor chip 120a by the pressure applied from an upper side of the first semiconductor chip 120a through the first die attach pressing process while a portion of the adhesive layer 122a is pushed upward along the side walls SW1 of the semiconductor chip 120a due to its wettability characteristics at a contact interface thereof. The second adhesive layer 122a′ formed on the first side wall SW1 of the first semiconductor chip 120a may have a slope shape.

Subsequently, referring to FIGS. 9C and 10, the first and second adhesive layers 122a and 122a′ may be cured over a predetermined time, and then a second semiconductor chip 120b may be mounted on the first semiconductor chip 120a (S330).

Subsequently, referring to FIGS. 9D and 10, a second die attach pressing process may be performed on the second semiconductor chip 120b arranged in the predetermined position of the package substrate 110 under a predetermined temperature condition (S340).

Subsequently, the performing of the mounting of the semiconductor chip and the die attach pressing process may be repeatedly performed a desire number of times, and then a curing process may be performed for structural stability thereof (S350). Subsequently, as described above, a conductive line printing process may be performed (S360) and an encapsulation process may be performed (S370). When the encapsulation process is terminated, the external connection terminal 50 such as a solder ball may be formed on the exposed lower pad 52 on the lower surface of the package substrate 110, thereby completing the semiconductor package shown in FIG. 6.

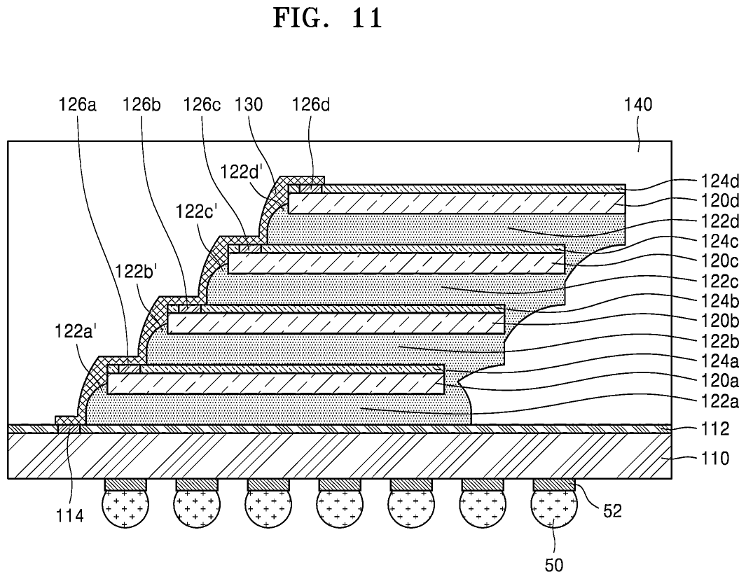

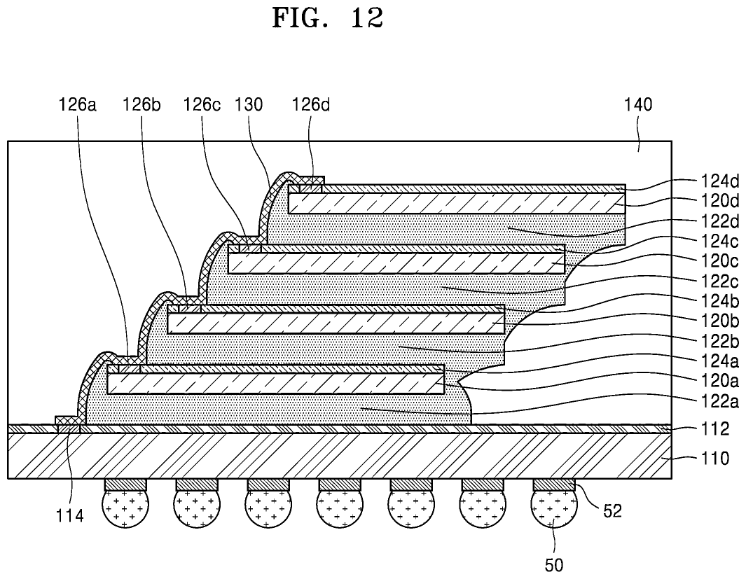

FIG. 11 is a cross-sectional view of a semiconductor package according to some embodiments. A semiconductor package shown in FIG. 11 where a plurality of semiconductor chips 120a-120d having the same size are stacked in the step shape, may be the same as the semiconductor package according to the embodiment shown in FIG. 6, except that upper ends of the second adhesive layers 122a′-122d′ formed along the first side walls SW1 of the plurality of semiconductor chips 120a-120d may only partially cover the first side walls SW1 thereof, respectively. When the first side walls SW1 of the plurality of semiconductor chips 120a-120d are completely electrically insulated, the amount of adhesive layers that are pushed in a horizontal direction from the first side walls of the plurality of semiconductor chips 120a-120d may preferably decrease.

FIG. 12 is a cross-sectional view of a semiconductor package according to some embodiments. A semiconductor package shown in FIG. 12 where a plurality of semiconductor chips 120a-120d having the same size are stacked in the step shape, may be the same as the semiconductor package according to the embodiment shown in FIG. 6, except that upper ends of the second adhesive layers 122a′-122d′ formed along the first side walls of the plurality of semiconductor chips 120a-120d may extend beyond the first side walls of semiconductor chips and partially cover a portion of upper surfaces of the semiconductor chips 120a-120d, respectively. When a portion of a semiconductor layer or a conductive layer in the plurality of semiconductor chips 120a-120d is exposed to the first side walls SW1 of the semiconductor chips, the embodiment of FIG. 12 may be preferable in that complete insulation characteristics of the plurality of semiconductor chip 120a-120d may be secured.

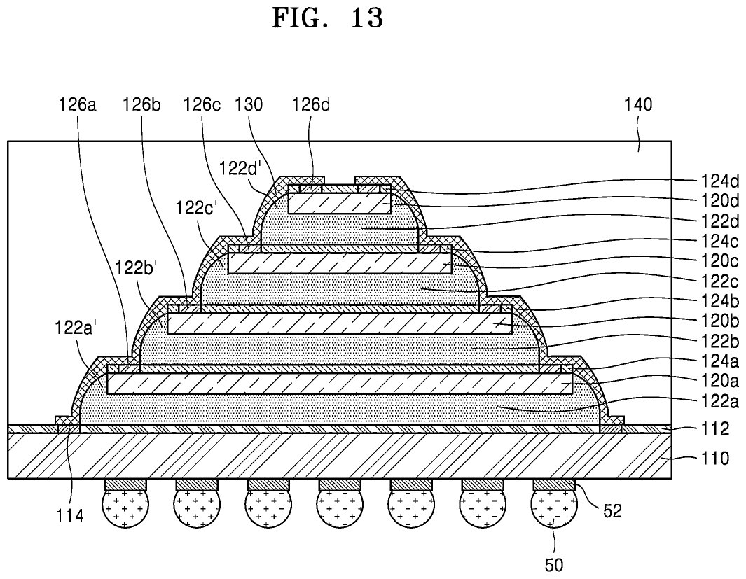

FIG. 13 is a cross-sectional view of a semiconductor package according to some embodiments. FIG. 13 shows a semiconductor package where the sizes of the plurality of semiconductor chips 120a-120d stacked on the package substrate 110 are different from each other. That is, the semiconductor package may be referred to as a pyramid-type semiconductor package in which the size of each of the semiconductor chips stacked on the package substrate 110 may decrease along a vertical direction extending away from the package substrate 110. FIG. 13 shows a case where all four side walls SW1-SW4 of the plurality of semiconductor chips 120a-120d are formed in the step shape, but is not limited thereto. In some embodiments, only one or more side walls of the four side walls thereof may be formed in the step shape.

The semiconductor package according to some embodiments may include micro processing units, memory, interfaces, graphics processing units, function blocks, and buses that connect them. In addition, a memory device including the semiconductor package according to some embodiments may be applied to an electronic system, and may be applied to an electronic device adopting the electronic system.

While aspects of the inventive concept have been particularly shown and described with reference to embodiments thereof, it will be understood that various changes in form and details may be made therein without departing from the spirit and scope of the following claims.

What is claimed is:

1. A semiconductor package comprising:
a package substrate comprising one or more first conductive pads on an upper surface thereof;
a semiconductor chip disposed on the package substrate and comprising one or more second conductive pads on an upper surface thereof;
a first adhesive layer, having electrical insulation characteristics, formed between the package substrate and the semiconductor chip;
a second adhesive layer, having electrical insulation characteristics, formed along a first side wall of the semiconductor chip; and
a conductive line electrically connecting the second conductive pad of the semiconductor chip to the first conductive pad of the package substrate, wherein
the first adhesive layer and the second adhesive layer include the same adhesive material and are formed continuously without a boundary therebetween by pressing the same adhesive material between the package substrate and the semiconductor chip, and
an outer surface of the second adhesive layer has a first slope extending downwardly and outwardly toward the upper surface of the package substrate from the first side wall.

2. The semiconductor package of claim 1, wherein the second adhesive layer contacts the first side wall of the semiconductor chip so that the conductive line is electrically insulated from the first side wall of the semiconductor chip.

3. The semiconductor package of claim 1, wherein
the semiconductor chip includes a second side wall opposing the first side wall,
the second adhesive layer being formed along the second side wall,
an outer surface of the second adhesive layer formed along the second side wall has a second slope extending downwardly and outwardly toward the upper surface of the package substrate from the second side wall, and
the first slope and the second slope are the same.

4. The semiconductor package of claim 1, wherein an inclination angle of the first slope of the second adhesive layer does not exceed about 45 degrees.

5. A semiconductor package comprising:
a package substrate comprising one or more first conductive pads on an upper surface thereof;
a plurality of semiconductor chips stacked on the package substrate, each semiconductor chip comprising one or more second conductive pads on each upper surface thereof, wherein respective first side walls of the plurality of semiconductor chips are stacked on each other to have a step shape;
a plurality of first adhesive layers, having electrical insulation characteristics, formed between the plurality of semiconductor chips and between the package substrate and the semiconductor chip arranged at a lowermost position among the plurality of semiconductor chips, the plurality of first adhesive layers insulating the plurality of semiconductor chips from each other;
a plurality of second adhesive layers, having electrical insulation characteristics, formed to correspond to each of the plurality of first adhesive layers along each first side wall of the plurality of semiconductor chips; and
a conductive line electrically connecting the second conductive pads of the semiconductor chips to the first conductive pad of the package substrate, wherein
the first adhesive layers and the second adhesive layers formed to correspond to each other are formed from the same adhesive material, and are formed continuously without a boundary therebetween by pressing the same adhesive material between the plurality of semiconductor chips and between the package substrate and the semiconductor chip arranged at the lowermost position among the plurality of semiconductor chips, and
outer surfaces of the second adhesive layers have a slope extending downwardly and outwardly toward the upper surface of the package substrate from the first side walls of the semiconductor chips.

6. The semiconductor package of claim 5, wherein
the second adhesive layers contact the first side walls of the semiconductor chips so that the conductive line is electrically insulated from the first side walls of the semiconductor chips.

7. The semiconductor package of claim 5, further comprising electrical insulating layers disposed between the conductive line and the first side walls of the plurality of semiconductor chips.

8. The semiconductor package of claim 5, wherein the slope of the second adhesive layers has a convex shape.

9. The semiconductor package of claim 5, wherein an inclination angle of the slope of the second adhesive layers does not exceed about 45 degrees.

10. The semiconductor package of claim 5, wherein each of the second adhesive layers correspondingly contact at least a portion of the first side wall of each of the semiconductor chips.

11. The semiconductor package of claim 5, wherein each of the second adhesive layers correspondingly contacts at least a portion of the upper surface of each of the semiconductor chips beyond the first side wall thereof.

12. The semiconductor package of claim 5, wherein
the plurality of semiconductor chips have the same size as each other,
the plurality of semiconductor chips each include a second side wall opposing a corresponding first side wall, a third side wall, and a fourth side wall opposing a corresponding second side wall, and
the plurality of semiconductor chips are aligned so that a plurality of third side walls of the plurality of semiconductor chips coincide with each other in a vertical direction and a plurality of fourth side walls thereof coincide with each other in the vertical direction, each of the first side walls is between each of the third side walls and each of the fourth side walls, and the conductive line is formed along the first side walls.

13. The semiconductor package of claim 12, wherein
a thickness of the first adhesive layer between the semiconductor chip arranged at the lowermost position among the semiconductor chips and the package substrate is greater than a thickness of the first adhesive layer between the plurality of semiconductor chips.

14. The semiconductor package of claim 12, wherein a thickness of the first adhesive layer between the plurality of semiconductor chips increases or decreases away from the package substrate.

15. The semiconductor package of claim 12, wherein
the plurality of semiconductor chips each include a second side wall opposing a corresponding first side wall,
the respective second side walls of the plurality of semiconductor chips are stacked on each other to have a reverse-step shape, and
the second adhesive layers are integrally formed along the second side walls of the plurality of semiconductor chips and are in contact with each other.

16. The semiconductor package of claim 5, wherein
the plurality of semiconductor chips have different surface areas, and the size of the surface areas of the semiconductor chips decrease in a direction extending away from the package substrate.

17. The semiconductor package of claim 16, wherein
the plurality of semiconductor chips each include a second side wall opposing a corresponding first side wall,
the second adhesive layer being formed along the second side wall of the respective semiconductor chips, and
the second adhesive layer formed along the first side wall of the respective semiconductor chips being symmetrical to the second adhesive layer formed along the second side wall of the respective semiconductor chips.

18. A semiconductor package comprising:
a package substrate comprising one or more first conductive pads on an upper surface thereof;
a plurality of semiconductor chips stacked on the package substrate and comprising first side walls stacked on each other to have a step shape, each semiconductor chip comprising one or more second conductive pads on each upper surface thereof;
a plurality of first adhesive layers, having electrical insulation characteristics, formed between the plurality of semiconductor chips and between the package substrate and the semiconductor chip arranged at a lowermost position among the plurality of semiconductor chips, and the plurality of first adhesive layers insulating the plurality of semiconductor chips from each other;
a plurality of second adhesive layers, having electrical insulation characteristics, formed to correspond to each of the plurality of first adhesive layers along each first side wall of the plurality of semiconductor chips;
a conductive line electrically connecting the second conductive pads of the semiconductor chips to the first conductive pad of the package substrate;
a sealing member sealing the plurality of semiconductor chips and the conductive line; and
a plurality of external terminals formed on the package substrate,
wherein the first adhesive layers and the second adhesive layers formed correspond to each other are formed from the same adhesive material, and are formed continuously without a boundary therebetween by pressing the same adhesive material between the plurality of semiconductor chips and between the package substrate and the semiconductor chip arranged at a lowermost position among the plurality of semiconductor chips, and
each of the second adhesive layers has a slope extending downwardly and outwardly toward the upper surface of the package substrate from the first side walls of the semiconductor chips.

19. The semiconductor package of claim 18, wherein the plurality of semiconductor chips have the same size as each other, and the conductive line is formed along the first side walls of the plurality of semiconductor chips.

20. The semiconductor package of claim 19, wherein
the plurality of semiconductor chips each include a second side wall opposing a corresponding first side wall,
the respective second side walls of the plurality of semiconductor chips are stacked on each other to have a reverse-step shape, and
the second adhesive layers are integrally formed along the second side walls of the plurality of semiconductor chips and are in contact with each other.
